(19) United States
(12) Patent Application Publication
(10) Pub. No.: US 2006/0166440 A1
(43) Pub. Date: Jul. 27, 2006

(54) Semiconductor nonvolatile memory device, and manufacturing method thereof

(75) Inventors: Tatsunori Kaneoka, Tokyo (JP); Yoshiki Maruyama, Tokyo (JP); Satoshi Yamamoto, Tokyo (JP); Toshiya Uenishi, Tokyo (JP)

Correspondence Address: MCDERMOTT WILL & EMERY LLP, 600 13TH STREET, N.W., WASHINGTON, DC, 20005-3096, US

(73) Assignee: RENESAS TECHNOLOGY CORP.

(21) Appl. No.: 11/335,504

(22) Filed: Jan. 20, 2006

(30) Foreign Application Priority Data
Jan. 24, 2005 (JP) JP2005-015189
Aug. 12, 2005 (JP) JP2005-354507

(51) Int. Cl. H01L 21/336; H01L 21/31

(52) U.S. Cl. 438/257; 438/263; 438/786

(57) ABSTRACT

The present invention realizes a semiconductor nonvolatile memory device where a leak current does not easily flow through a tunnel insulating film, and a manufacturing method thereof A silicon nitride oxide film constituting a tunnel insulating film is formed by radically nitriding a surface of a silicon oxide film. The film formed by a radical nitriding process makes it difficult for defects to occur in the film, in comparison with a nitride film formed by a CVD method. In addition, the radical nitriding process causes less plasma damage, in comparison with a conventional simple plasma nitriding process. It is therefore possible to obtain a semiconductor nonvolatile memory device where a leak current does not easily flow through a tunnel insulating film.

### BACKGROUND OF THE INVENTION

1. Field of the Invention

The present invention relates to a semiconductor nonvolatile memory device having a tunnel insulating film, and a manufacturing method thereof.

2. Description of the Background Art

In a third embodiment of Japanese Patent Application Laid-Open No. 11-317463 (1999), there is described a tunnel insulating film 1 of a semiconductor nonvolatile memory device which has a layered structure of a thermal oxide film 21 and a nitride film 23 formed by a CVD (Chemical Vapor Deposition) method.

In addition, in paragraph “0026” of Japanese Patent Application Laid-Open No. 2004-47614, there is described a tunnel insulating film 15a of a semiconductor nonvolatile memory device, which is constituted by a layered film where a plasma nitride film is layered on a plasma oxide film.

If the nitride film portion of a tunnel insulating film of a semiconductor nonvolatile memory device is formed by a CVD method, defects easily occur in the nitride film. In addition, if a nitride film portion of a tunnel insulating film is formed by a simple plasma nitriding process, the nitride film is easily damaged by plasma.

When aforementioned defects or damages occur in the nitride film, it becomes easy for a leak current to flow through the tunnel insulating film. As a result, the data storing ability of the semiconductor nonvolatile memory device is lowered.

Even when a nitride film is additionally formed on the silicon oxide film, reduction in the rate of data erasure in the semiconductor nonvolatile memory device due to an increase in the interface state in the interface between the oxide film portion and the semiconductor substrate such as the silicon substrate does not improve.

### SUMMARY OF THE INVENTION

The present invention is made in view of the aforementioned circumstances, and an object of the present invention is to realize a semiconductor nonvolatile memory device and a manufacturing method thereof where a leak current does not easily flow through a tunnel insulating film and to realize a semiconductor device and a manufacturing method thereof where an interface state in an interface between the tunnel insulating film and a semiconductor substrate does not easily increase.

According to a first aspect of the present invention, there is provided a manufacturing method of a semiconductor nonvolatile memory device that includes a tunnel insulating film. The method includes (a) a step of forming a silicon oxide film constituting the tunnel insulating film on a semiconductor substrate, and (b) a step of forming a first silicon nitride oxide film constituting the tunnel insulating film on the silicon oxide film. Herein, in the step (b), a surface of the silicon oxide film is radically nitrided, so that the first silicon nitride oxide film is formed.

According to a second aspect of the present invention, there is provided a semiconductor nonvolatile memory device including a semiconductor substrate, a silicon oxide film formed on the semiconductor substrate, and a silicon nitride oxide film formed on the silicon oxide film. Herein, the silicon oxide film and the silicon nitride oxide film constitute a tunnel insulating film, and the silicon nitride oxide film is formed by radically nitriding a surface of the silicon oxide film.

According to a third aspect of the present invention, there is provided a semiconductor nonvolatile memory device including a semiconductor substrate, a silicon oxide film, a first silicon nitride oxide film formed on the silicon oxide film, and a second silicon nitride oxide film formed between the semiconductor substrate and the silicon oxide film. Herein, the silicon oxide film as well as the first and second silicon nitride oxide films constitute a tunnel insulating film.

According to the first aspect of the present invention, the surface of the silicon oxide film is radically nitrided, so that the first silicon nitride oxide film is formed. The film formed by a radical nitriding process makes it difficult for defects to occur in the film, in comparison with a nitride film formed by a CVD method. In addition, the radical nitriding process can reduce damage caused by plasma, in comparison with a conventional simple plasma nitriding process. It is therefore possible to manufacture a semiconductor nonvolatile memory device where a leak current does not easily flow through a tunnel insulating film.

According to the second aspect of the present invention, the silicon nitride oxide film constituting the tunnel insulating film is formed by radically nitriding the surface of the silicon oxide film. The film formed by a radical nitriding process makes it difficult for defects to occur in the film, in comparison with a nitride film formed by a CVD method. In addition, the radical nitriding process can reduce damage caused by plasma, in comparison with a conventional simple plasma nitriding process. It is therefore possible to obtain a semiconductor nonvolatile memory device where a leak current does not easily flow through a tunnel insulating film.

According to the third aspect of the present invention, the tunnel insulating film is constituted by the silicon oxide film as well as the first and second silicon nitride oxide films. The second silicon nitride oxide film is formed between the silicon oxide film and the semiconductor substrate. Therefore, defects do not easily occur in the interface between the tunnel insulating film and the semiconductor substrate. It is possible to obtain a semiconductor nonvolatile memory device where an interface state in the interface between the tunnel insulating film and the semiconductor substrate does not easily increase. Accordingly, the tunnel insulating film can further be strengthened; thus, it is possible to obtain a semiconductor nonvolatile memory device where a leak current does not easily flow through the tunnel insulating film.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 shows a semiconductor nonvolatile memory device according to a first embodiment;

FIG. 2 shows a manufacturing method of the semiconductor nonvolatile memory device according to the first embodiment;

FIG. 3 shows the manufacturing method of the semiconductor nonvolatile memory device according to the first embodiment;

FIG. 4 shows the manufacturing method of the semiconductor nonvolatile memory device according to the first embodiment;

FIG. 5 shows the manufacturing method of the semiconductor nonvolatile memory device according to the first embodiment;

FIG. 6 shows an effect of the nonvolatile semiconductor memory device according to the first embodiment;

FIG. 7 shows a semiconductor nonvolatile memory device according to a second embodiment;

FIG. 8 shows a manufacturing method of the semiconductor nonvolatile memory device according to the second embodiment;

FIG. 9 shows the manufacturing method of the semiconductor nonvolatile memory device according to the second embodiment;

FIG. 10 shows the manufacturing method of the semiconductor nonvolatile memory device according to the second embodiment; and

FIG. 11 shows an effect of the nonvolatile semiconductor memory device according to the second embodiment.

### DESCRIPTION OF THE PREFERRED EMBODIMENTS

### First Embodiment

A first embodiment is directed to a semiconductor nonvolatile memory device where a silicon nitride oxide film that constitutes a tunnel insulating film is formed by radically nitriding a surface of a silicon oxide film, and a manufacturing method thereof.

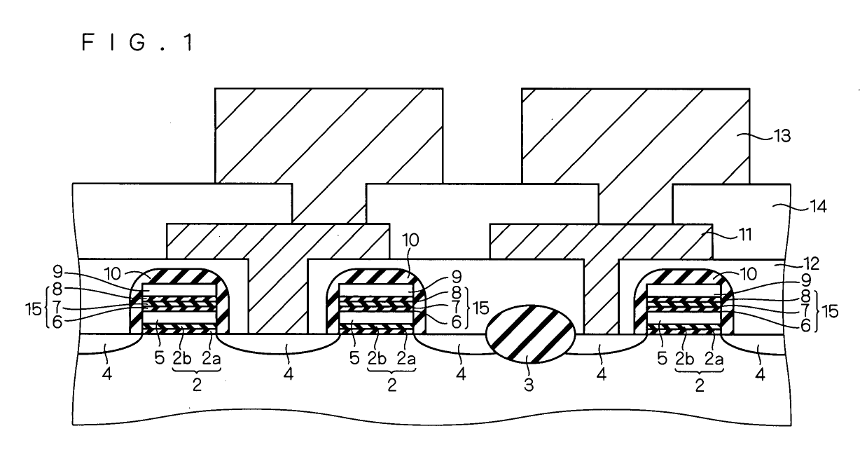

FIG. 1 shows the semiconductor nonvolatile memory device according to this embodiment. As shown in FIG. 1, this semiconductor nonvolatile memory device includes a semiconductor substrate 1 such as a silicon substrate.

An element isolation region 3 of which the main component is a silicon oxide film, and source/drain regions 4 which are components of the semiconductor nonvolatile memory device are formed on a surface of the semiconductor substrate 1. Here, the source/drain regions 4 are active regions which are formed by selectively making n-type impurities such as phosphorous or arsenic diffuse into portions on the surface of the semiconductor substrate 1.

Silicon oxide films 2a are formed on the semiconductor substrate 1, and silicon nitride oxide films 2b are formed on the silicon oxide films 2a. These silicon nitride oxide films 2b are formed by radically nitriding the surfaces of the silicon oxide films 2a, as will be described below. In addition, each layered film constituted by the silicon oxide film 2a and the silicon nitride oxide film 2b functions as a tunnel insulating film 2 of one memory cell of the semiconductor nonvolatile memory device.

A floating gate electrode 5, of which the main component is polysilicon to which impurities such as phosphorous are added, is formed on the tunnel insulating film 2. In addition, a layered film of a silicon oxide film 6, a silicon nitride film 7 and a silicon oxide film 8 is formed on the floating gate electrode 5. This layered film functions as a charge holding film 15 for one memory cell of the semiconductor nonvolatile memory device.

A control gate electrode 9, of which the main component is polysilicon to which impurities such as phosphorous are added, is formed on the charge holding film 15. In addition, an electrically insulating film 10, of which the main component is a silicon oxide film, is formed so as to cover an upper face and side faces of the control gate electrode 9 as well as side faces of the charge holding film 15, floating gate electrode 5 and tunnel insulating film 2. The electrically insulating film 10 is provided in order to achieve electrical insulation between adjacent memory cells of the semiconductor nonvolatile memory device.

An interlayer insulating film 12, of which the main component is a silicon oxide film, is formed on the semiconductor substrate 1 so as to cover the element isolation regions 3, the electrically insulating films 10 and the source/drain regions 4. In addition, another interlayer insulating film 14 is formed on the interlayer insulating film 12 as an upper layer.

Contact metal wires 11 are formed inside the interlayer insulating film 12 and on a surface of the interlayer insulating film 12 so as to be electrically connected to the source/drain regions 4. In addition, contact metal wires 13 are formed inside the interlayer insulating film 14 and on a surface of the interlayer insulating film 14 so as to be electrically connected to the contact metal wires 11.

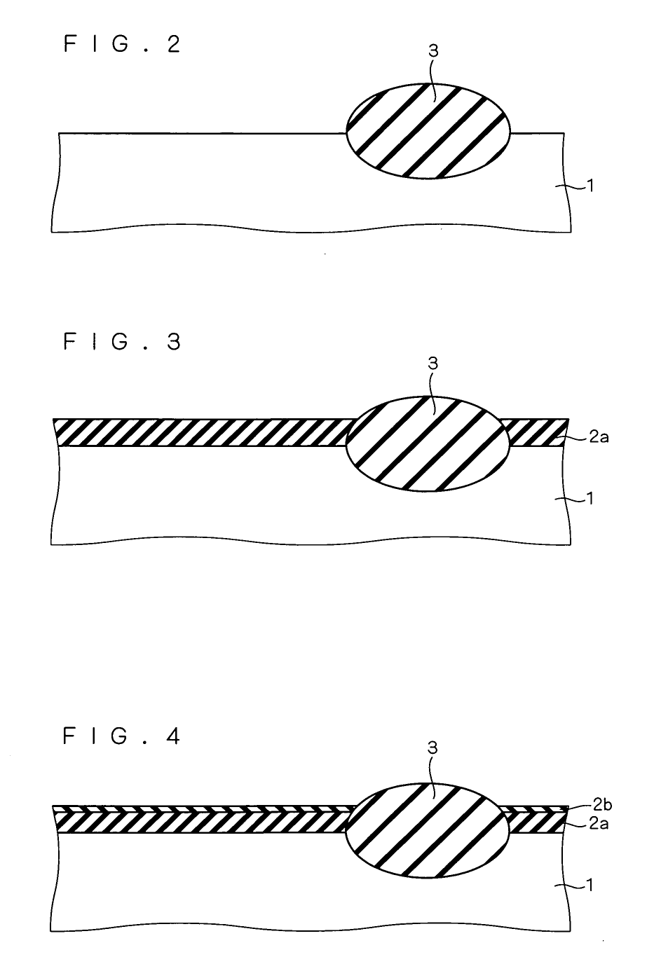

Next, a manufacturing method of the semiconductor nonvolatile memory device according to this embodiment is described with reference to FIGS. 2 to 5.

First, as shown in FIG. 2, an element isolation region 3 is formed in a predetermined region on a surface of a semiconductor substrate 1 by a thermal oxidation method or the like.

Next, as shown in FIG. 3, a silicon oxide film 2a which constitutes a tunnel insulating film 2 is formed on the semiconductor substrate 1. This silicon oxide film 2a may be formed by, for example, a thermal oxidation method. More specifically, the silicon oxide film 2a may be formed by, for example, a pyrogenic oxidation method utilizing combustion reaction of hydrogen and oxygen at 650° C. to 900° C., or a radical oxidation method utilizing oxidized radicals which are generated through reaction of oxygen and hydrogen at a temperature from 650° C. to 1150° C. under a pressure of 50 Torr or less.

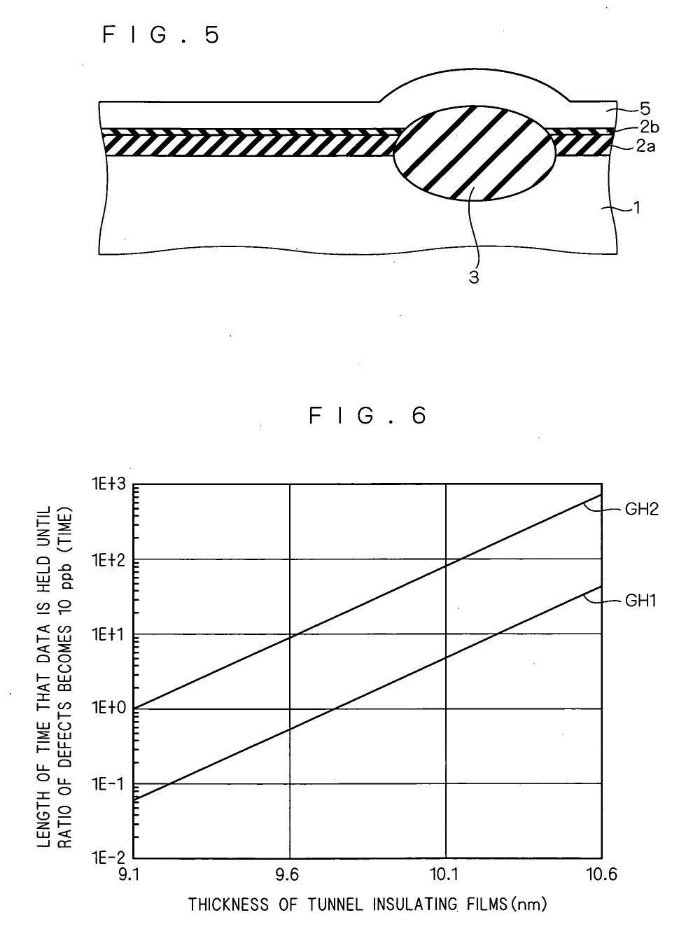

Next, as shown in FIG. 4, a silicon nitride oxide film 2b which constitutes the tunnel insulating film 2 is formed on the silicon oxide film 2a. This silicon nitride oxide film 2b is formed by radically nitriding a surface of the silicon oxide film 2a. Concretely, nitrogen radicals which are obtained during the process of decomposing nitrogen diluted with argon into plasma may be utilized.

In the conventional plasma nitridation method, high energy plasma is generated by DC glow discharge of a nitrogen-including gas, and ions of nitrogen molecule obtained by the generated plasma heats up an object and activates a surface of the object. On the other hand, in the radical nitridation method, glow discharge of a nitrogen-including gas is precisely controlled. By this operation, it is possible to carry out a nitridation with effective generation of highly-activated radical, and with generation of plasma of low ion density and low enegy.

As for the conditions for radical nitridation, for example, the power of microwaves in a radical nitridation apparatus for decomposing nitrogen into plasma may be set at 1 kW to 4 kW, the ratio of the flow amount between the argon gas and the nitrogen gas may be set to argon:nitrogen=1:0.02 to 0.1, the temperature may be set to 250° C. to 600° C., and the pressure may be set to 0.1 Torr to 5 Torr.

At this time, the surface of the silicon oxide film 2a is placed at a sufficient distance from the high density plasma region that has been generated by the microwaves, so that the number of nitrogen ions, which are a cause of plasma damage and make contact with the surface of the silicon oxide film 2a, is reduced. Further, the number of nitrogen radicals is increased, so that a silicon nitride oxide film 2b having few defects can be formed.

Here, when a silicon nitride oxide film 2b that was actually formed by the present inventors under these conditions was analyzed in accordance with X-ray photoelectron spectroscopy (XPS), it was found that a thickness of approximately 1 nm was obtained. In addition, the content of nitrogen within the silicon nitride oxide film 2b can be adjusted by setting appropriate conditions for radical nitridation, such as the ratio of the flow amount of the argon gas to the nitrogen gas, the pressure and the time for nitridation.

Next, as shown in FIG. 5, a conductive film that becomes floating gate electrodes 5 is formed on the silicon nitride oxide film 2b. The conductive film serving as floating gate electrodes 5 can be formed by a CVD method, using, for example, monosilane (SiH₄) and phosphine (PH₃). The temperature at the time of formation is set at, for example, 500° C. to 550° C., so that the floating gate electrodes 5 are formed as polysilicon films to which phosphorous has been added. Here, the concentration of the added phosphorous can be controlled by setting the ratio of the gas flow amount of monosilane (SiH₄) to phosphine (PH₃).

Next, a silicon oxide film 6, a silicon nitride film 7 and a silicon oxide film 8 are formed on the conductive film serving as the floating gate electrodes 5 by a CVD method. Further, a conductive film serving as the control gate electrodes 9 is formed by the same manufacturing method as that of the conductive film serving as the floating gate electrodes 5.

Thereafter, the layered structure up to the conductive film serving as the control gate electrodes 9 is patterned using photolithographic and etching technologies, so that the layered structure of FIG. 1 having the tunnel insulating films 2, the floating gate electrodes 5, the charge holding films 15 and the control gate electrodes 9 is formed.

With the semiconductor nonvolatile memory device and the manufacturing method thereof according to this embodiment, the surface of the silicon oxide film 2a is radically nitrided, so that the silicon nitride oxide film 2b which constitutes the tunnel insulating film 2 is formed. The film formed through a radical nitriding process makes defects difficult to occur in the film, in comparison with nitride films formed by a CVD method. In addition, a radical nitriding process causes less plasma damage, in comparison with a conventional simple plasma nitriding process. It is therefore possible to manufacture a semiconductor nonvolatile memory device where a leak current does not easily flow through the tunnel insulating films 2.

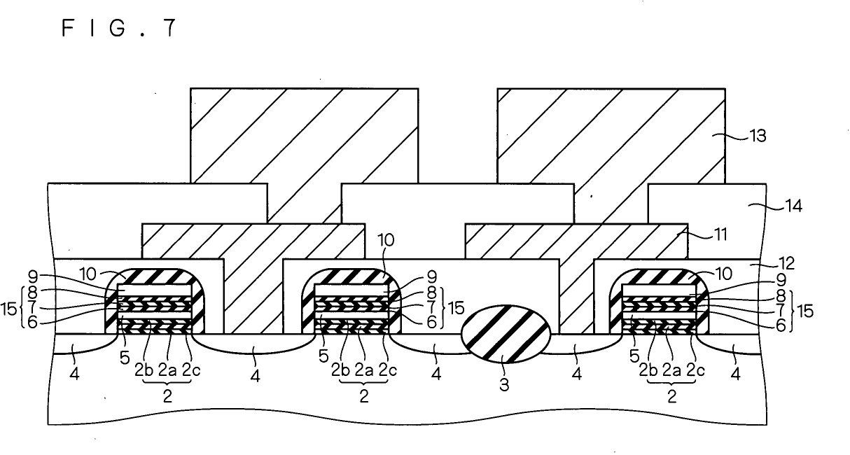

FIG. 6 shows an effect of the semiconductor nonvolatile memory device according to this embodiment, by comparing data holding properties of the semiconductor nonvolatile memory device according to this embodiment with data holding properties of a conventional semiconductor nonvolatile memory device.

In FIG. 6, the longitudinal axis indicates the length of time that data is held until the ratio of defects becomes 10 ppb (parts per billion), and the lateral axis indicates the thickness of the tunnel insulating film 2. In this graph, a line GH1 indicates the data holding properties of the conventional semiconductor nonvolatile memory device, and a line GH2 indicates the data holding properties of the semiconductor nonvolatile memory device according to this embodiment.

As can be seen from the values of line GH2, the data holding properties of the semiconductor nonvolatile memory device according to this embodiment are such that the length of time that data is held ten or more times longer than in conventional semiconductor nonvolatile memory device. This means that a leak current does not easily flow through the tunnel insulating films 2; therefore, the charge holding ability of the semiconductor nonvolatile memory device according to this embodiment is extremely high.

### Second Embodiment

A second embodiment is directed to modifications of the semiconductor nonvolatile memory device and the manufacturing method thereof according to the first embodiment, where additional silicon nitride oxide films which constitute the tunnel insulating film 2 are formed between the silicon oxide films 2a and the semiconductor substrate 1 according to the first embodiment.

FIG. 7 shows a semiconductor nonvolatile memory device according to this embodiment. As shown in FIG. 7, this semiconductor nonvolatile memory device is different from the semiconductor nonvolatile memory device of FIG. 1 in the following point. That is, this semiconductor nonvolatile memory device includes additional silicon nitride oxide films 2c which are formed between the semiconductor substrate I and the silicon oxide films 2a. In addition, each layered film which is constituted by the silicon oxide film 2a and the silicon nitride oxide films 2b and 2c functions as a tunnel insulating film 2 of one memory cell of the semiconductor nonvolatile memory device.

As described above, the tunnel insulating films 2 are constituted by the silicon oxide films 2a and the silicon nitride oxide films 2b and 2c. Consequently, the tunnel insulating films 2 can be strengthened; thus, it is possible to obtain a semiconductor nonvolatile memory device where a leak current does not easily flow through the tunnel insulating film 2. In addition, the silicon nitride oxide films 2c are formed between the semiconductor substrate 1 and the silicon oxide film 2a; thus, it is possible to obtain a semiconductor nonvolatile memory device where defects do not easily occur in the interface between the tunnel insulating film 2 and the semiconductor substrate 1 and an interface state in the interface between the tunnel insulating film and the semiconductor substrate does not easily increase.

The other parts of the configuration are the same as those of the semiconductor nonvolatile memory device according to the first embodiment; therefore, the descriptions thereof are omitted

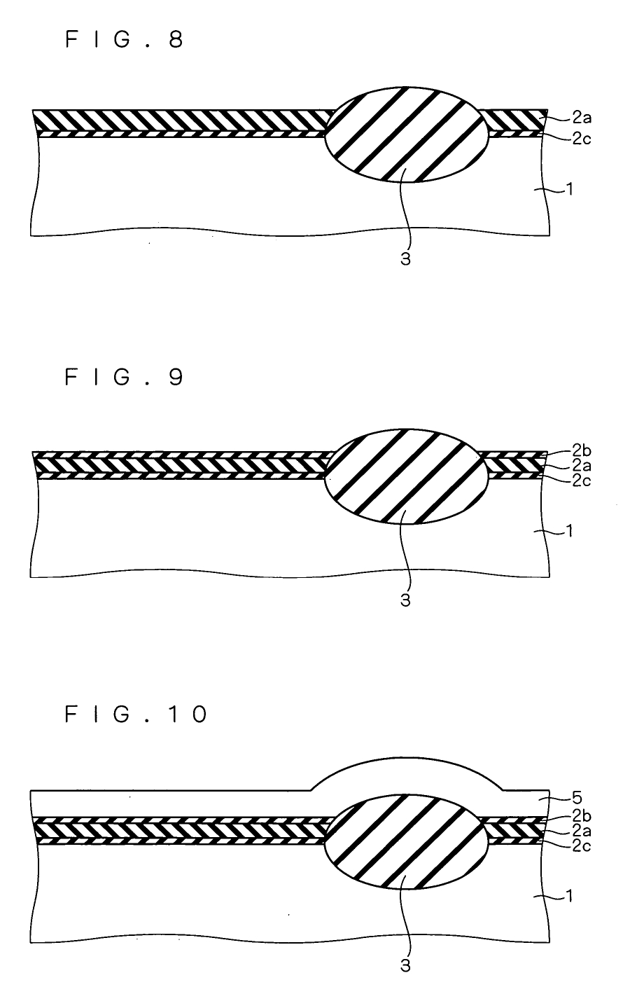

Next, a manufacturing method of the semiconductor nonvolatile memory device according to this embodiment is described with reference to FIGS. 8 to 10.

First, in the same manner as in FIGS. 2 and 3 of the first embodiment, an element isolation region 3 is formed on a surface of a semiconductor substrate 1 by a thermal oxidation method or the like. Thereafter, a silicon oxide film 2a is formed on the semiconductor substrate 1 by a thermal oxidation method or the like.

Next, as shown in FIG. 8, a silicon nitride oxide film 2c is formed between the silicon oxide film 2a and the semiconductor substrate 1. This silicon nitride oxide film 2c is formed by carrying out an annealing process (the temperature for processing may be, for example, 800° C. to 1150° C.) in an atmosphere of nitrogen monoxide (NO), nitrous oxide (N₂O) or ammonium (NH₃).

Next, as shown in FIG. 9, the surface of the silicon oxide film 2a is radically nitrided, so that a silicon nitride oxide film 2b is formed on the silicon oxide film 2a. The conditions for radical nitridation may be the same as in the case of the first embodiment.

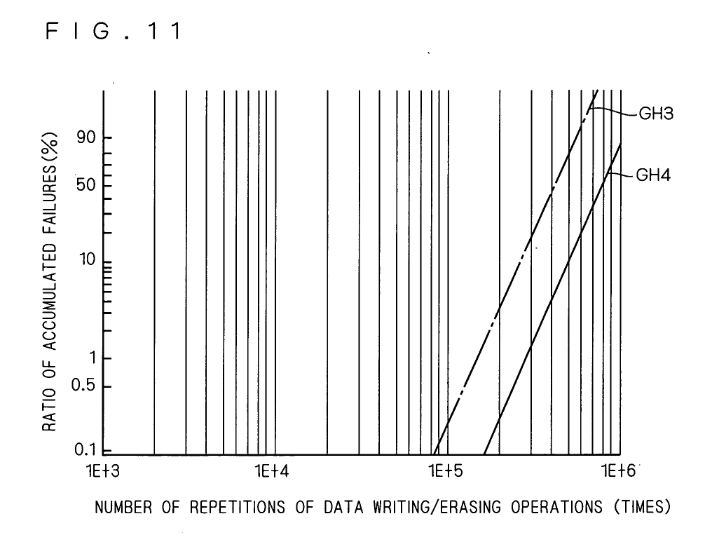

Next, as shown in FIG. 10, a conductive film serving as floating gate electrodes 5 is formed on the silicon nitride oxide film 2b, in the same manner as in the case of the first embodiment.

Next, a silicon oxide film 6, a silicon nitride film 7 and a silicon oxide film 8 are formed on the conductive film serving as the floating gate electrodes 5 by a CVD method. Further, a conductive film serving as control gate electrodes 9 is formed by the same manufacturing method as that of the conductive film serving as the floating gate electrodes 5.

Thereafter, the layered structure up to the conductive layer serving as the control gate electrodes 9 is patterned using photolithographic and etching technologies, so that the layered structure of FIG. 7 having tunnel insulating films 2, floating gate electrodes 5, charge holding films 15 and control gate electrodes 9 is formed.

Also in the semiconductor nonvolatile memory device according to this embodiment, the silicon nitride oxide film 2b is formed by radically nitriding the surface of the silicon oxide film 2a. It is therefore possible to obtain a semiconductor nonvolatile memory device where a leak current does not easily flow through the tunnel insulating films 2.

In addition, the manufacturing method of the semiconductor nonvolatile memory device according to this embodiment further includes a step of carrying out an annealing process in an atmosphere of nitrogen monoxide, nitrous oxide or ammonium to form a silicon nitride oxide film 2c constituting the tunnel insulating film 2 between the silicon oxide film 2a and the semiconductor substrate 1. Accordingly, the tunnel insulating film 2 can further be strengthened; thus, it is possible to manufacture a semiconductor nonvolatile memory device where a leak current does not easily flow and defects do not easily occur in an interface between the tunnel insulating film and the semiconductor substrate and an interface state in the interface between the tunnel insulating film 2 and the semiconductor substrate I does not easily increase.

FIG. 11 shows an effect of the semiconductor nonvolatile memory device according to this embodiment, by comparing the ratio of defective data erasing operations caused by reduction in the rate of data erasure in the semiconductor nonvolatile memory device according to this embodiment with the ratio of defective data erasing operations in a semiconductor nonvolatile memory device having tunnel insulating film made of two layers, silicon oxide films 2a and silicon nitride oxide films 2b, without silicon nitride oxide films 2c.

In FIG. 1, the longitudinal axis indicates the ratio of the accumulated number of times that defective data erasing operations occurred, and the lateral axis indicates the number of repetitions of data writing operations and data erasing operations. In this graph, a line GH3 indicates the ratio of defective data erasing operations of the semiconductor nonvolatile memory device having tunnel insulating films made of two layers, silicon oxide films 2a and silicon nitride oxide films 2b, without silicon nitride oxide films 2c, and a line GH4 indicates the ratio of defective data erasing operations of the semiconductor nonvolatile memory device according to this embodiment.

As can be seen from the values of the line GH4, the ratio of defective data erasing operations of the semiconductor nonvolatile memory device according to this embodiment is lower than the ratio of defective data erasing operations of the semiconductor nonvolatile memory device having tunnel insulating films made of two layers, silicon oxide films 2a and silicon nitride oxide films 2b. This means that increase in the interface state between the tunnel insulating films 2 and the semiconductor substrate 1 is not easily caused by repetition of data writing operations and data erasing operations; therefore, reduction in the rate of data erasure in the semiconductor nonvolatile memory device according to this embodiment is extremely small.

The present inventors obtained excellent results in the same manner as in the case of FIG. 6, in terms of the data holding properties of the semiconductor nonvolatile memory device according to this embodiment.

While the invention has been shown and described in detail, the foregoing description is in all aspects illustrative and not restrictive. It is therefore understood that numerous modifications and variations can be devised without departing from the scope of the invention.

What is claimed is:

1. A manufacturing method of a semiconductor nonvolatile memory device that includes a tunnel insulating film, comprising the steps of:
(a) forming a silicon oxide film constituting said tunnel insulating film on a semiconductor substrate; and
(b) forming a first silicon nitride oxide film constituting said tunnel insulating film on said silicon oxide film, wherein
in said step (b), a surface of said silicon oxide film is radically nitrided, so that said first silicon nitride oxide film is formed.

2. The manufacturing method of a semiconductor nonvolatile memory device according to claim 1, further comprising the step of:
(c) carrying out an annealing process in an atmosphere of nitrogen monoxide, nitrous oxide or ammonium to form a second silicon nitride oxide film constituting said tunnel insulating film between said silicon oxide film and said semiconductor substrate, after said step (a) and before said step (b).

3. A semiconductor nonvolatile memory device comprising:
a semiconductor substrate;
a silicon oxide film formed on said semiconductor substrate; and
a silicon nitride oxide film formed on said silicon oxide film, wherein
said silicon oxide film and said silicon nitride oxide film constitute a tunnel insulating film, and
said silicon nitride oxide film is formed by radically nitriding a surface of said silicon oxide film.

4. A semiconductor nonvolatile memory device comprising:
a semiconductor substrate;
a silicon oxide film;
a first silicon nitride oxide film formed on said silicon oxide film; and
a second silicon nitride oxide film formed between said semiconductor substrate and said silicon oxide film, wherein
said silicon oxide film as well as said first and second silicon nitride oxide films constitute a tunnel insulating film.

5. The semiconductor nonvolatile memory device according to claim 4, wherein
said first silicon nitride oxide film is formed by radically nitriding a surface of said silicon oxide film.
